(19) United States
(12) Patent Application Publication
(10) Pub. No.: US 2017/0244259 A1
(43) Pub. Date: Aug. 24, 2017

(54) VOLTAGE DETECTING DEVICE

(71) Applicant: KEIHIN CORPORATION, Tokyo (JP)

(72) Inventors: Shingo Tsuchiya, Shioya-gun (JP); Seiji Kamata, Kakuda-shi (JP)

(73) Assignee: KEIHIN CORPORATION, Tokyo (JP)

(21) Appl. No.: 15/416,264

(22) Filed: Jan. 26, 2017

(30) Foreign Application Priority Data
Feb. 19, 2016 (JP) 2016-029806

(51) Int. Cl. H02J 7/00; G01R 31/36; B60L 11/18

(52) U.S. Cl. CPC H02J 7/0021; B60L 11/1812; H02J 7/0068; G01R 31/362; G01R 31/3658; B60L 11/1861

(57) ABSTRACT

A voltage detecting device includes a plurality of batteries, a plurality of filters each including a resistor and a capacitor, a plurality of discharge circuits each including a resistor, a switch, and a capacitor connected in parallel to the switch, a first voltage detecting circuit that includes a first filter among the plurality of filters and a first discharge circuit among the plurality of discharge circuits and detects voltage of a first battery among the plurality of batteries, a second voltage detecting circuit that includes a second filter among the plurality of filters and a second discharge circuit among the plurality of discharge circuits and detects voltage of a second battery among the plurality of batteries, and a detecting unit that controls the switch and detects disconnection between the battery and the discharge circuit based on outputs of the first and second voltage detecting circuits.

### CROSS REFERENCE TO RELATED APPLICATION

The present application claims priority under 35 U.S.C. §119 to Japanese Patent Application No. 2016-029806 filed in the Japan Patent Office on Feb. 19, 2016, the entire content of which is hereby incorporated by reference.

### TECHNICAL FIELD

The present invention relates to a voltage detecting device.

### BACKGROUND OF THE INVENTION

In vehicles such as an electric car and a hybrid car, a high-voltage, high-capacity battery that supplies power to a motor serving as a source of power is mounted. This battery for motor driving is composed of plural battery cells connected in series. Furthermore, each of the battery cells connected in series is provided with a voltage detecting circuit and the voltage of each battery cell is monitored. It is described that, in such a battery monitoring system, a denoising filter that removes noise is provided between each single battery cell and the voltage detecting circuit (for example, refer to Japanese patent laid-open publication No. 2013-205173 (“JP '173”)). This denoising filter is a circuit composed of a resistor and a capacitor. In the technique described in JP '173, a charge is stored in the capacitor the denoising filter has.

Furthermore, in a battery monitoring system described in Japanese patent laid-open publication No. 2013-085354 (“JP '354”), a discharge circuit in which a switching element and a resistor are connected in series is provided between each battery cell and a corresponding voltage detecting circuit. This discharge circuit is used for cell balance control in which the battery cell in an over-charged state is discharged to equalize the respective battery cell voltages. Furthermore, in this battery-monitoring system, the duty ratios of the switching elements corresponding to adjacent battery cells are set different, and disconnection of an interconnect led out from a connecting node between the adjacent battery cells is detected by using a threshold about the potential difference between the adjacent battery cells.

### SUMMARY OF THE INVENTION

However, in the technique described in JP '173, for example if disconnection occurs between the battery cell and the denoising filter, it is difficult to properly detect the voltage of each battery cell due to the charge stored in the relevant capacitor. If discharging the charge of the capacitor is attempted by operating a constant current source IO the battery monitoring system described in JP '173 has (see FIG. 4 in JP '173), it is difficult for the charge of the capacitor to be discharged in a short time if the value of a resistor Ra connected between the denoising filter and the constant current source IO is not set large. However, when the value of the resistor Ra is set large, heat generated by the resistor Ra and the scale of the voltage detecting circuit increase.

Furthermore, in the technique described in JP '354, there is a limit to the discharge time for which discharge is carried out by the discharge circuit. Thus, when disconnection occurs, a long time is taken until the potential difference between the adjacent battery cells increases and surpasses the threshold, and it takes a long time to detect the disconnection in some cases.

The present invention is made in view of the above-described point and intends to provide a voltage detecting device that can shorten the detection time of disconnection in a power supply detecting device that detects the voltage of a power supply in which plural battery cells are connected.

To solve the above-described problems, a battery voltage detecting device according to one embodiment of the present invention includes a plurality of batteries, a plurality of filters, a plurality of discharge circuits, a first voltage detecting circuit, a second voltage detecting circuit, and a detecting unit. The plurality of filters each includes a resistor and a capacitor. The plurality of discharge circuits each includes a resistor, a switch, and a capacitor connected in parallel to the switch. The first voltage detecting circuit includes a first filter among the plurality of filters and a first discharge circuit among the plurality of discharge circuits and detects the voltage of a first battery among the plurality of batteries. The second voltage detecting circuit includes a second filter among the plurality of filters and a second discharge circuit among the plurality of discharge circuits and detects the voltage of a second battery among the plurality of batteries. The detecting unit controls the switch and detects disconnection between the battery and the discharge circuit based on an output of the first voltage detecting circuit and an output of the second voltage detecting circuit.

Furthermore, in the battery voltage detecting device according to the one embodiment of the present invention, a resistance value possessed by the filter may be larger than a resistance value possessed by the discharge circuit.

In addition, in the battery voltage detecting device according to the one embodiment of the present invention, the detecting unit may switch an on-state and an off-state of the switch of the discharge circuit for a predetermined period to discharge a charge stored in the capacitor of the filter, and acquire the output of the first voltage detecting circuit and the output of the second voltage detecting circuit after the discharge.

Moreover, in the battery voltage detecting device according to the one embodiment of the present invention, the detecting unit may carry out operation of switching the on-state and the off-state of the switch of the discharge circuit for the predetermined period a predetermined number of times and acquire the outputs of the first voltage detecting circuit and the second voltage detecting circuit after discharge subsequent to the predetermined number of times of the operation, and the detecting unit may detect that disconnection has occurred between the second battery and the second discharge circuit when the difference between the output of the first voltage detecting circuit and the output of the second voltage detecting circuit that are acquired is equal to or larger than a threshold.

According to the present invention, the detection time of disconnection can be shortened in a power supply detecting device that detects the voltage of a power supply in which plural battery cells are connected.

### BRIEF DESCRIPTION OF THE DRAWINGS

The advantages of this invention will become apparent in the following description taken in conjunction with the drawings, wherein:

FIG. 1 is a configuration schematic diagram of a voltage detecting device according to an embodiment of the present invention;

FIG. 2 is a diagram showing one example of the operation waveforms of switches, the output waveform of a differential circuit, the output waveform of another differential circuit, and the disconnection detection timing of a detecting unit when disconnection has occurred according to the embodiment;

FIG. 3 is a diagram showing the output waveform of the differential circuit, the output waveform of the other differential circuit, and the waveform of change in the voltage between both ends of the switch when disconnection has occurred according to the embodiment; and

FIG. 4 is a diagram showing operation when disconnection has not occurred and operation when disconnection has occurred according to the embodiment.

### DETAILED DESCRIPTION OF THE INVENTION

An embodiment of the present invention will be described below with reference to the drawings.

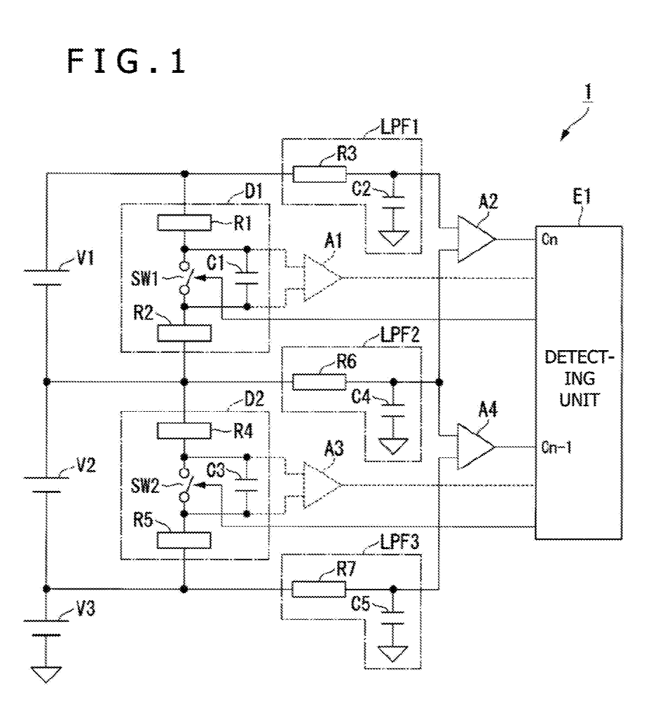

FIG. 1 is a configuration schematic diagram of a voltage detecting device 1 according to the present embodiment. As shown in FIG. 1, the voltage detecting device 1 includes battery cells V1 to V3, discharge circuits D1 and D2, low-pass filters LPF1 to LPF3, differential circuits A1 to A4, and a detecting unit E1. The discharge circuit D1 includes a resistor R1, a resistor R2, a capacitor C1, and a switch SW1. The discharge circuit D2 includes a resistor R4, a resistor R5, a capacitor C3, and a switch SW2. The low-pass filter LPF1 includes a resistor R3 and a capacitor C2. The low-pass filter LPF2 includes a resistor R6 and a capacitor C4. The low-pass filter LPF3 includes a resistor R7 and a capacitor C5. The voltage detecting device 1 does not need to have the differential circuits A1 and A3. When one of the battery cells V1 to V3 is not specified, the battery cells V1 to V3 will be referred to simply as the battery cell V. When one of the discharge circuits D1 and D2 is not specified, the discharge circuits D1 and D2 will be referred to simply as the discharge circuit D. When one of the low-pass filters LPF1 to LPF3 is not specified, the low-pass filters LPF1 to LPF3 will be referred to simply as the LPF.

In the battery cell V1 (first battery), the positive side is connected to one end of the resistor R1 and one end of the resistor R3. Furthermore, one side of the negative side is connected to the positive side of the battery cell V2 (second battery) and the other side of the negative side is connected to one end of the resistor R2, one end of the resistor R4, and one end of the resistor R6.

In the battery cell V2 (second battery), the positive side is connected to the negative side of the battery cell V1, the one end of the resistor R2, the one end of the resistor R4, and the one end of the resistor R6. Furthermore, one side of the negative side is connected to the positive side of the battery cell V3 (third battery) and the other side of the negative side is connected to one end of the resistor R5 and one end of the resistor R7.

In the battery cell V3 (third battery), the positive side is connected to the negative side of the battery cell V2, the one end of the resistor R5, and the one end of the resistor R7, and the negative side is grounded.

One end of the discharge circuit D1 (first discharge circuit) is connected to the positive side of the battery cell V1 and the one end of the resistor R3. The other end of the discharge circuit D1 is connected to the negative side of the battery cell V1, the positive side of the battery cell V2, the one end of the resistor R4, and the one end of the resistor R6. Furthermore, in the discharge circuit D1, the resistor R1, the switch SW1, and the resistor R2 are connected in series and the capacitor C1 is connected in parallel to the switch SW1. The other end of the resistor R1 is connected to one end of the switch SW1 and one end of the capacitor C1. In the switch SW1, the other end is connected to the other end of the resistor R2 and the other end of the capacitor C1 and a control terminal is connected to the detecting unit E1. Furthermore, the other end of the resistor R1, the one end of the switch SW1, and the one end of the capacitor C1 are connected to one input terminal of the differential circuit A1. The other end of the resistor R2, the other end of the switch SW1, and the other end of the capacitor C1 are connected to the other input terminal of the differential circuit A1.

One end of the discharge circuit D2 (second discharge circuit) is connected to the negative side of the battery cell V1, the positive side of the battery cell V2, the one end of the resistor R2, and the one end of the resistor R6. The other end of the discharge circuit D2 is connected to the negative side of the battery cell V2, the positive side of the battery cell V3, and the one end of the resistor R7. Furthermore, in the discharge circuit D2, the resistor R4, the switch SW2, and the resistor R5 are connected in series and the capacitor C3 is connected in parallel to the switch SW2. The other end of the resistor R4 is connected to one end of the switch SW2 and one end of the capacitor C3. In the switch SW2, the other end is connected to the other end of the resistor R5 and the other end of the capacitor C3 and a control terminal is connected to the detecting unit E1. Furthermore, the other end of the resistor R4, the one end of the switch SW2, and the one end of the capacitor C3 are connected to one input terminal of the differential circuit A3. The other end of the resistor R5, the other end of the switch SW2, and the other end of the capacitor C3 are connected to the other input terminal of the differential circuit A3. When one of the switch SW1 and the switch SW2 is not identified, the switches SW1 and SW2 will be referred to simply as the switch SW. The capacitance of the capacitors C1 and C3 is several microfarads for example.

An input end of the low-pass filter LPF1 (first filter) is connected to the positive side of the battery cell V1 and the one end of the resistor R1. An output end of the low-pass filter LPF1 is connected to one input terminal of the differential circuit A2. The other end of the resistor R3 is connected to one end of the capacitor C2 and the one input terminal of the differential circuit A2. The other end of the capacitor C2 is grounded. The resistance value of the resistor R3 is larger than the resistance value of the resistor R1 and the resistor R2 in the discharge circuit D1. For example, the resistance value of the resistor R1 and the resistor R2 is several tens of ohms and the resistance value of the resistor R3 is several kilo-ohms.

An input end of the low-pass filter LPF2 (second filter) is connected to the negative side of the battery cell V1, the positive side of the battery cell V2, the one end of the resistor R2, and the one end of the resistor R4. An output end of the low-pass filter LPF2 is connected to the other input terminal of the differential circuit A2 and one input terminal of the differential circuit A4. The other end of the resistor R6 is connected to one end of the capacitor C4, the other input terminal of the differential circuit A2, and the one input terminal of the differential circuit A4. The other end of the capacitor C4 is grounded. The resistance value of the resistor R6 is larger than the resistance value of the resistor R4 and the resistor R5 in the discharge circuit D2. For example, the resistance value of the resistor R4 and the resistor R5 is several tens of ohms and the resistance value of the resistor R6 is several kilo-ohms.

An input end of the low-pass filter LPF3 (third filter) is connected to the negative side of the battery cell V2, the positive side of the battery cell V3, and the one end of the resistor R5. An output end of the low-pass filter LPF3 is connected to the other input terminal of the differential circuit A4. The other end of the resistor R7 is connected to one end of the capacitor C5 and the other input terminal of the differential circuit A4. The other end of the capacitor C5 is grounded.

An output terminal of the differential circuit A1 is connected to the detecting unit E1. An output terminal of the differential circuit A3 is connected to the detecting unit E1. An output terminal of the differential circuit A2 is connected to a Cn terminal of the detecting unit E1. An output terminal of the differential circuit A4 is connected to a Cn−1 terminal of the detecting unit E1. The output of the differential circuit A1 is the voltage between both ends of the switch SW1 and the output of the differential circuit A3 is the voltage between both ends of the switch SW2. The output of the differential circuit A2 is equivalent to the voltage difference between the negative electrode and the positive electrode of the battery cell V1. The output of the differential circuit A4 is equivalent to the voltage difference between the negative electrode and the positive electrode of the battery cell V2.

In the present embodiment, the discharge circuit D1, the low-pass filter LPF1, and the differential circuit A2 refer to a first voltage detecting circuit. Furthermore, in the present embodiment, the discharge circuit D2, the low-pass filter LPF2, and the differential circuit A4 refer to a second voltage detecting circuit.

The battery cells V1 and V2 are lithium ion batteries for example. The switches SW1 and SW2 are mechanical switches, field effect transistors (FETs), or the like for example.

The detecting unit E1 is a central processing unit (CPU) for example. The detecting unit E1 controls the on-state and off-state of the switches SW1 and SW2 a predetermined number of times at every predetermined cycle. The detecting unit E1 acquires a voltage value output by the differential circuit A2 at predetermined timing and a voltage value output by the differential circuit A4, and detects whether or not disconnection has occurred based on the voltage difference between the voltage value output by the differential circuit A2 and the voltage value output by the differential circuit A4 after the predetermined number of times of the control. The disconnection detected by the detecting unit E1 is disconnection of a connecting part between the battery cell V and the discharge circuit D. The control method of the switches SW1 and SW2 and the detection method by the detecting unit E1 will be described later.

Next, an operation example of the voltage detecting device 1 will be described.

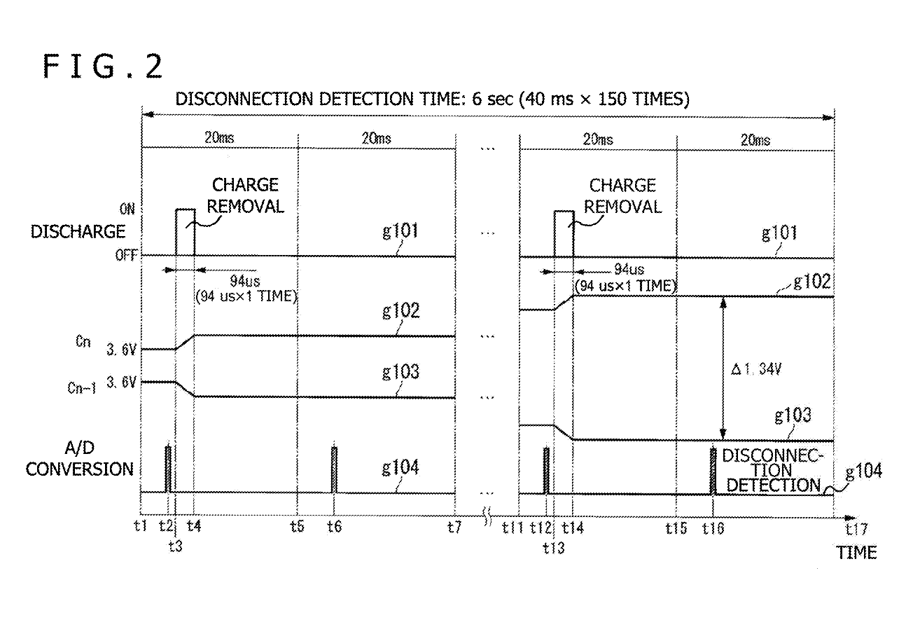

FIG. 2 is a diagram showing one example of the operation waveforms of the switches SW1 and SW2, the output waveform of the differential circuit A2, the output waveform of the differential circuit A4, and the disconnection detection timing of the detecting unit E1 when disconnection has occurred according to the present embodiment. In FIG. 2, the abscissa axis represents the time and the ordinate axis represents the levels of the respective signals. Furthermore, a waveform g101 represents the operation waveforms of the switches SW1 and SW2. A waveform g102 represents the output waveform of the differential circuit A2 and a waveform g103 represents the output waveform of the differential circuit A4. A waveform g104 represents the disconnection detection timing of the detecting unit E1.

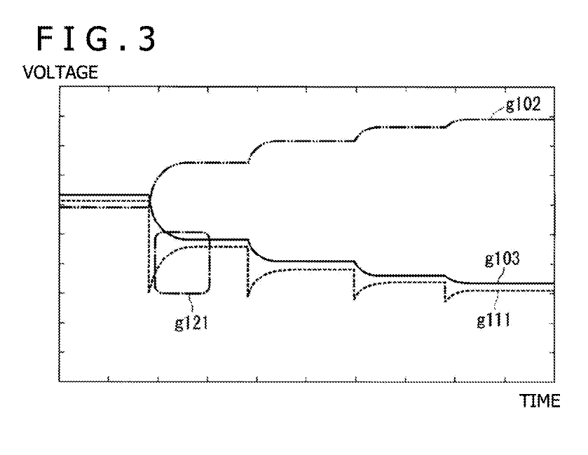

FIG. 3 is a diagram showing the output waveform of the differential circuit A2, the output waveform of the differential circuit A4, and the waveform of change in the voltage between both ends of the switch SW when disconnection has occurred according to the present embodiment. In FIG. 3, the abscissa axis represents the time and the ordinate axis represents the levels of the respective signals. Furthermore, a waveform g111 is the waveform of the voltage between both ends of the switch SW. In the waveform g111, it is shown that the switch SW is controlled to the off-state when the voltage decreases. Furthermore, as in a region shown by symbol g121, the voltage slowly recovers compared with the related art due to the capacitor C1 or C3 included in the discharge circuit D when the switch SW becomes the off-state after being set to the on-state. In addition, in the present embodiment, charge removal is carried out during the period in which the voltage recovers.

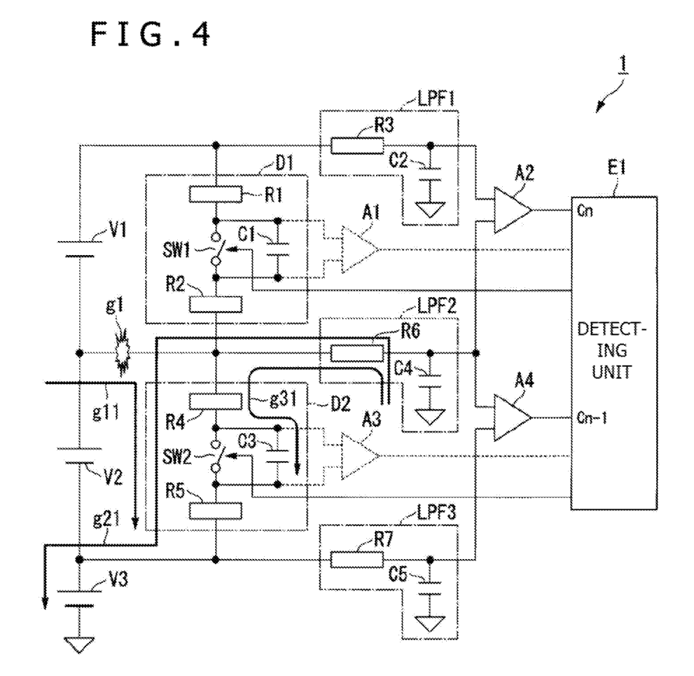

FIG. 4 is a diagram showing operation when disconnection has not occurred and operation when disconnection has occurred according to the present embodiment. In the present embodiment, the disconnection is disconnection that occurs between the battery cell V and the discharge circuit D, and includes connection failure, contact failure, and disconnection of a connector or harness when the battery cell V and the discharge circuit D are connected via the connector or harness. In FIG. 4, symbol g1 denotes disconnection.

As shown in FIG. 2, in the present embodiment, the detecting unit E1 repeatedly detects disconnection a predetermined number of times (for example 150 times) at every predetermined cycle (for example 40 ms). In FIG. 2, the analog-to-digital (A/D)-converted waveform represents the timings at which the detecting unit E1 detects disconnection.

In a period of a time t1 to t3, the detecting unit E1 controls each of the switches SW1 and SW2 to the off-state.

At the time t2, the detecting unit E1 acquires a voltage value Cn output by the differential circuit A2 and a voltage value Cn−1 output by the differential circuit A4. The time t2 is a time in 20 ms of a charge removal period as the first half of the predetermined cycle 40 ms.

In a period of the time t3 to t4 (for example 94 μs), the detecting unit E1 switches the on-state and off-state of each of the switches SW1 and SW2 at predetermined duty ratios. As the predetermined duty ratios, for example, the on-state and off-state of the switch SW1 are 4% and 96% respectively, and the on-state and off-state of the switch SW2 are 96% and 4%, respectively. By switching the on-state and off-state of the switches SW1 and SW2, the detecting unit E1 removes the charge stored in the capacitors (C2, C4) of the LPFs. Furthermore, by switching the switches SW1 and SW2 at such duty ratios, the voltage value Cn output by the differential circuit A2 increases from e.g. 3.6 V over time and the voltage value Cn−1 output by the differential circuit A4 decreases from e.g. 3.6 V over time as shown in FIG. 2 and FIG. 3 (refer to JP '354). The duty ratios may be fixed or may be controlled through change by the detecting unit E1.

At a time t6, the detecting unit E1 acquires a voltage value Cn output by the differential circuit A2 and a voltage value Cn−1 output by the differential circuit A4. The time t6 is a time in 20 ms of a detection period as the second half of the predetermined cycle 40 ms.

The detecting unit E1 repeats the processing of the time t1 to t7 the predetermined number of times. In the discharge circuit D1, in which the period of the on-state of the switch SW1 is short, a current flows less readily and thus the voltage increases in every round of the processing. In the discharge circuit D2, in which the period of the on-state of the switch SW2 is long, a current flows readily and thus the voltage decreases in every round of the processing. If disconnection has occurred, due to the repetition of this processing, the voltage value Cn output by the differential circuit A2 increases in every cycle from 3.6 V toward 5 V for example and the voltage value Cn−1 output by the differential circuit A4 decreases in every cycle from 3.6 V toward 0 V for example as shown in FIG. 3.

The detecting unit E1 calculates the absolute value Δ of the difference between the voltage value Cn and the voltage value Cn−1 detected at a time t16 in the detection period in the predetermined-number-th (for example 150-th) round, and determines whether or not the calculated absolute value Δ is equal to or larger than a predetermined voltage value (for example 1.34 V). If the absolute value Δ is equal to or larger than the predetermined voltage value (for example threshold of 1.34 V), the detecting unit E1 determines that disconnection has occurred at the place of symbol g1 shown in FIG. 4.

Next, the operation of the voltage detecting device 1 when disconnection has not occurred and when disconnection has occurred will be described. In the following description, the case in which disconnection has not occurred at the place of symbol g1 and the case in which disconnection has occurred at this place will be described.

At the time of charge removal, the detecting unit E1 controls the switch SW1 of the discharge circuit D1 or the switch SW2 of the discharge circuit D2 to the on-state.

When disconnection has not occurred, a closed circuit of the battery cell V1 and the discharge circuit D1 is formed and the voltage of the battery cell V1 is applied to the discharge circuit D1. Furthermore, a closed circuit of the battery cell V2 and the discharge circuit D2 is formed and the voltage of the battery cell V2 is applied to the discharge circuit D2. When the switch SW1 becomes the on-state and then becomes the off-state, the discharge circuit D1 becomes a circuit having a time constant based on the resistor R1, the resistor R2, and the capacitor C1 and carries out discharge (charge removal) of the capacitors C2 and C4 of the LPFs in this period. When the switch SW2 becomes the on-state and then becomes the off-state, as shown by symbol g11, the discharge circuit D2 becomes a circuit having a time constant based on the resistor R4, the resistor R5, and the capacitor C3 and carries out discharge (charge removal) in this period. Because the time constants are smaller than those when disconnection has occurred, the voltage of the capacitors C1 and C3 rapidly recovers compared with the case in which disconnection has occurred.

If disconnection has occurred at the place of symbol g1, a closed circuit of the battery cell V1, the battery cell V2, the discharge circuit D1, and the discharge circuit D2 is formed and the voltages of the battery cell V1 and the battery cell V2 are applied to the discharge circuit D1 and the discharge circuit D2. When the switch SW1 becomes the on-state and then becomes the off-state, the discharge circuit D1 becomes a circuit having a time constant based on the resistor R3, the resistor R1, and the capacitor C1 and carries out discharge (charge removal) in this period. When the switch SW2 becomes the on-state and then becomes the off-state, as shown by symbols g21 and g31, the discharge circuit D2 becomes a circuit having a time constant based on the resistor R6, the resistor R4, and the capacitor C3 and carries out discharge (charge removal) in this period. This time constant is larger than that when disconnection has not occurred (hereinafter, referred to as non-disconnection case). Because the time constant is large compared with the non-disconnection case, the voltage of the capacitor C3 of the discharge circuit D2 recovers more slowly than in the non-disconnection case. For this reason, in the non-disconnection case, the output of the differential circuit A2 increases from 3.6 V toward 5 V for example and the output of the differential circuit A4 decreases from 3.6 V toward 0 V for example as shown in FIG. 2 and FIG. 3.

As above, in the present embodiment, the capacitor C3 (or C1) is connected in parallel to the switch SW2 (or SW1) in the discharge circuit D2 (or D1). Due to this, in the present embodiment, when the switch SW2 is in the off-state after discharge is carried out, if disconnection has occurred, the voltage of the capacitor C3 of the discharge circuit D2 recovers more slowly than in the non-disconnection case in the path of the resistor R6 to the capacitor C3 as shown in FIG. 3 because the resistor R6 is larger than the resistor R4 in the resistance value. On the other hand, if disconnection has not occurred, the voltage of the capacitor C3 rapidly recovers compared with the case in which disconnection has occurred because the resistor R4 is smaller than the resistor R6 in the resistance value.

Furthermore, if disconnection has occurred, the output value of the differential circuit A2 increases and the output value of the differential circuit A4 decreases in every charge removal as shown in FIG. 3.

If disconnection has not occurred, the voltage rapidly recovers compared with the case of disconnection and thus the absolute value Δ of the difference between the voltage value Cn and the voltage value Cn−1 after the predetermined number of times of charge removal is smaller than the predetermined voltage value (threshold). On the other hand, if disconnection has occurred, the voltage recovers more slowly than in the non-disconnection case and thus the amounts of decrease and increase of the voltage per predetermined number of times of charge removal are larger than in the case in which disconnection has not occurred. Due to this, the absolute value Δ of the difference between the voltage value Cn and the voltage value Cn−1 becomes equal to or larger than the predetermined voltage value (threshold).

As described above, in the present embodiment, the capacitor (C1, C3) is connected in parallel to the switch SW of the discharge circuit D and thus the amount of charge removal can be increased compared with the related art. As a result according to the present embodiment, compared with the related art, the time until reaching to the threshold when disconnection has occurred can be set short and thus the detection time of disconnection can be shortened. Due to this, according to the embodiment, the time it takes to detect disconnection can be shortened and therefore the effect that time shortening to safe operation can be carried out is also achieved.

The present invention is not limited to the above-described embodiment. For example, in the above-described example, the example in which the number of battery cells V is three and the number of discharge circuits D is two and the number of LPFs is three is shown. However, the configuration is not limited thereto. The number of battery cells V may be four or more. For example, if a configuration includes four battery cells V1 to V4 (not shown), the configuration may include three discharge circuits D1 to D3 (not shown), low-pass filters LPF1 to LPF4 (not shown), and a differential circuit A5 (not shown). In this case, one end of the battery cell V4 is grounded and the other end of the battery cell V4 is connected to the other end of the battery cell V3. The output of the differential circuit A5 is equivalent to the potential difference between both ends of the battery cell V3. In this case, the detecting unit E1 can detect disconnection of a connecting part among the positive side of the battery cell V3, the resistor R5, and the resistor R7 based on the output difference between the differential circuit A4 and the differential circuit A5.

It should be understood by those skilled in the art that various modifications, combinations, sub-combinations and alterations may occur depending on design requirements and other factors insofar as they are within the scope of the appended claims or the equivalents thereof.

We claim:

1. A voltage detecting device comprising:
a battery cell including a first battery and a second battery;
a discharge circuit, the discharge circuit including
a first discharge circuit including a first resistor, a first switch, and a first capacitor, and
a second discharge circuit including a second resistor, a second switch, and a second capacitor;
a first voltage detecting circuit that detects a voltage of the first battery, the first voltage detecting circuit including:
a first filter including a third resistor and a third capacitor, and
the first discharge circuit;
a second voltage detecting circuit that detects a voltage of the second battery, the second voltage detecting circuit including:
a second filter including a fourth resistor and a fourth capacitor, and
the second discharge circuit; and
a detecting unit that controls the first switch and the second switch and detects disconnection between the battery cell and the discharge circuit based on an output of the first voltage detecting circuit and an output of the second voltage detecting circuit.

2. The voltage detecting device according to claim 1, wherein
a resistance value possessed by the first filter is larger than a resistance value possessed by the first discharge circuit, and
a resistance value possessed by the second filter is larger than a resistance value possessed by the second discharge circuit.

3. The voltage detecting device according to claim 1, wherein
the detecting unit switches an on-state and an off-state of the first switch of the first discharge circuit for a predetermined period to discharge a charge stored in the third capacitor of the first filter, and switches an on-state and an off-state of the second switch of the second discharge circuit for the predetermined period to discharge a charge stored in the fourth capacitor of the second filter, and acquires the output of the first voltage detecting circuit and the output of the second voltage detecting circuit after the discharge.

4. The voltage detecting device according to claim 3, wherein
the detecting unit carries out operation of switching the on-state and the off-state of the first switch of the first discharge circuit and the second switch of the second discharge circuit for the predetermined period a predetermined number of times and acquires the outputs of the first voltage detecting circuit and the second voltage detecting circuit after discharge subsequent to the predetermined number of times of the operation, and
the detecting unit detects that disconnection has occurred between the second battery and the second discharge circuit when difference between the output of the first voltage detecting circuit and the output of the second voltage detecting circuit that are acquired is equal to or larger than a threshold.
